(19) United States
(12) Patent Application Publication
(10) Pub. No.: US 2013/0024135 A1
(43) Pub. Date: Jan. 24, 2013

(54) Method And Apparatus For Ferromagnetic Cable Inspection

(71) Applicant: Dieter W. Blum, Aldergrove (CA)

(72) Inventor: Dieter W. Blum, Aldergrove (CA)

(21) Appl. No.: 13/553,770

(22) Filed: Jul. 19, 2012

Related U.S. Application Data
(60) Provisional application No. 61/511,010, filed on Jul. 22, 2011.

(51) Int. Cl. G06F 19/00; G01R 33/12

(52) U.S. Cl. 702/38; 324/234

(57) ABSTRACT

An opposing field sensing element for ferromagnetic cable inspection is disclosed that uses magnetic flux sources and a magnetic flux sensor to detect anomalies in ferromagnetic cables. An array of opposing field sensing elements may be used to non-invasively inspect systems that contain ferromagnetic cables such as conveyer belts and the like. The opposing field sensing element is small and compact, and immune to vertical axis flutter and disturbances of the ferromagnetic cable being inspected. In addition, the opposing field sensing element does not magnetize the ferromagnetic cable being inspected such that interference with other sensing and control systems is minimized.

This application claims priority to U.S. Patent Application Ser. No. 61/511,010 filed Jul. 22, 2011 entitled “Method And Apparatus For Ferromagnetic Cable Inspection” by Blum. The disclosure of this U.S. Patent Application Ser. No. 61/511,010 is incorporated herein by reference in its entirety.

### BACKGROUND OF THE INVENTION

1. Field of the Invention

The present invention relates generally to non-invasive test and measurement, and more particularly to a method and apparatus for ferromagnetic cable inspection.

2. Description of Related Art

Various means for the detection of damage, faults, and anomalies in elongate and longitudinal ferromagnetic members and elements have been employed over the years. Examples include x-ray inspection, as well as eddy current and leakage flux detection. Of these techniques, the detection of leakage flux from magnetized elongate ferromagnetic objects such as wire rope, strands and rods is the oldest and best known and understood. More than 150 years ago, simple compasses were used as single point static flux probes. This technique was followed by the use of induction coils wherein the translation velocity & leakage Magnetic field (B-field) cross-product induced an Electromotive Force (EMF), with either the object under inspection translating past a stationary sensing coil or with the sensing coil translating past a stationary object to be inspected.

At first, the output of a sensing coil was used to drive a galvanometer for manual observation. Later, the output of a sensing coil was used to drive a galvanometer based strip chart recorder pen mechanism for a permanent record. Later still, electronic versions of the strip-chart recorder were used, most recently with the use of virtual strip-chart recorders such as may be implemented on a computer.

In some applications, for example, those with a high-safety factor and those involving human transport, sensing coils that completely encircle the object to be tested are used. This technique is applied to suspension bridge cables, hoist and elevator cables, tramway cables, and the like. This technique provided for maximum sensitivity to leakage flux clue to strand breakages/anomalies.

In the above, correction for change in voltage with respect to time (dv/dt) distortion was initially accomplished by controlling sensor and object translation velocity, and then later, via measurement of translation velocity and the application of mathematical correction in software.

However, effects such as distortions due to the size of object, sensor standoff distance, and strength of its internal magnetization due to permeability and retentivity all require manual calibration procedures.

Further, in some applications, such as the inspection of steel reinforcing cables utilized in high-tension conveyor belts, multiple sensor induction coils were used in order to span a large number of transversally spaced-apart ferromagnetic elongate members that may include up to 30 or more per coil. An obvious side effect of this is the summation by a sensing coil of the leakage flux from each and all of the cables spanned by the coil. This approach provides a very confusing signal that is difficult to interpret and can lead to the cancellation, nullification and masking of defects and anomalies when approximately equal magnitude, but opposite polarity, flux leakages occur at the same instance in time.

In the above, it is obvious that either permanent magnet structures or electromagnets may be employed in order to pre-magnetize the ferromagnetic members. A side effect, unless degaussing is employed, is that the cables remain permanently magnetized. This can lead to interference issues with some recently employed methods to monitor conveyor belt splice growth, elongation and deterioration. Of further note is that leakage flux magnitude is on the order of 3-15 Gauss at the normal standoff distances employed.

Various examples of leakage flux methods and apparatus, particularly for wire rope, include U.S. Pat. No. 1,322,405 to C. W. Burrows, U.S. Pat. No. 4,427,940 to Hirama et al., and U.S. Pat. No. 4,827,215 to van der Walt. The entire disclosure of these patents being incorporated herein by reference.

Other inspection methods and apparatus measure a change in magnetic reluctance, such as, for example, due to actual loss of magnetically permeable material in the subject under inspection. This has an advantage in that defect and anomaly signals can be almost an order of magnitude greater than those obtained via leakage flux, for example, 20-100 Gauss.

This variable reluctance approach can be said to be velocity independent (especially if leakage flux is absent) if one can guarantee no permanent magnetic (B) field at the sensing plane so that just the steel cord permeability coupling of induced magnetic field (B) becomes the measure of reluctance and material presence or absence.

Examples of variable reluctance methods and apparatus, particularly as applied to the inspection of steel cables within high tension conveyor belts, include U.S. Pat. No. 4,439,731 to A. Harrison, the entire disclosure of which is incorporated herein by reference.

In the '731 patent to Harrison, Alternating Current (AC) generated magnetic (B) fields are injected and coupled into the cables by one or more (for example, 3-4+) scanner segments spanning the belt width, one above and one below the belt to provide for differential belt flutter cancellation. Each scanner segment comprises an exciter coil and a sensing coil, and each scanner segment covers a representative portion of the belt, thereby summing the signals from a corresponding number of cables within each coil, again with negative consequences as pointed out in the similar leakage flux sensing approach previously discussed.

This technique was commercially deployed as the “CBM” scanning system in the early 1980's and is still copied and in use today for low resolution scanning. Of note, in its practical use form, this system was slightly modified, first by using a Direct Current (DC) magnetic (B) field to standardize the cables ahead of the scanner segments, and second, by using physical belt stabilization (such as steady rolls) to eliminate belt flutter, thereby removing the need for scanner segments on both sides of the belt.

Another example of a variable reluctance method and apparatus, particularly as applied towards the inspection of steel cables within high tension conveyor belts, includes U.S. Pat. No. 5,847,563 to D. W. Blum, the entire disclosure of which is incorporated herein by reference.

The approach disclosed in the '563 patent to Blum utilizes a multitude (for example, 300 per 3 meters of belt width) of discrete static flux sensors, thereby providing vastly improved transverse spatial resolution and eliminating, the previously mentioned signal summing problem.

The apparatus disclosed in the '563 patent to Blum was commercially deployed as the “BELT CAT” scanning system in the mid-1990's and has since been widely used worldwide in order to provide for high-resolution scanning. Although unintended, these techniques suffer from remnant cable magnetization unless degaussing down stream from the pre-magnetization and sensing area is employed.

Some more recent variants, particularly those that are applied towards the inspection of steel cables within high tension conveyor belts, include the use of a multitude of discrete static flux sensors akin to the '563 patent to Blum, coupled with cable magnetization, providing a leakage flux inspection and scanning system.

It is therefore an object of the present invention to provide for a variable reluctance sensing topology that leaves little or no remnant magnetization in the object being inspected. It is a further object of the present invention to provide for a variable reluctance sensing topology that is insensitive to vertical flutter and displacement of the object being inspected. It is another object of the present invention to provide for a variable reluctance sensing topology that provides for greatly increased sensitivity at normally employed standoff distances. It is still a further object of the present invention to provide for a variable reluctance sensing topology that minimizes the mass of the magnetic excitation core. These and other objects of the present invention and the various embodiments described, depicted and envisioned herein will become evident after reading this specification with the attached drawings and claims.

### BRIEF SUMMARY OF THE INVENTION

In accordance with the present invention, there is provided an opposing field sensing element for ferromagnetic cable inspection comprising a first flux source and a second flux source wherein like polarities of the first flux source and the second flux source face each other, a magnetic flux sensor situated between the first flux source and the second flux source, and a magnetic flux concentrator located proximate said magnetic flux sensor.

The foregoing paragraph has been provided by way of introduction, and is not intended to limit the scope of the invention as described by this specification, claims and the attached drawings.

### BRIEF DESCRIPTION OF THE DRAWINGS

The invention will be described by reference to the following drawings, in which like numerals refer to like elements, and in which:

FIG. 1 is a side view of the opposing field sensing element according to the present invention in the presence of an intact magnetically permeable member such as a cable;

FIG. 2 is a side view of the opposing field sensing element according to the present invention in the presence of a broken or damaged magnetically permeable member such as a cable;

FIG. 3 is a functional block diagram depicting a system of the present invention;

FIG. 4 shows a typical environment of the present invention;

FIG. 5 shows a plan view of a typical environment of the present invention;

FIG. 6 shows a side view of a typical environment of the present invention;

FIG. 7 shows a perspective view of a typical environment of the present invention;

FIG. 8 shows a section of conveyer belt in use with the present invention;

FIG. 9 shows a side view of a single conveyer belt in use with the present invention;

FIG. 10 shows a cutaway view alone, line A-A of FIG. 8;

FIG. 11 is a functional block diagram of an n-channel opposing field sensing element array; and

FIG. 12 is a flowchart depicting a method of the present invention;

The present invention will be described in connection with a preferred embodiment, however, it will be understood that there is no intent to limit the invention to the embodiment described. On the contrary, the intent is to cover all alternatives, modifications, and equivalents as may be included within the spirit and scope of the invention as defined by this specification, claims and the attached drawings.

### DESCRIPTION OF THE PREFERRED EMBODIMENTS

For a general understanding of the present invention, reference is made to the drawings. In the drawings, like reference numerals have been used throughout to designate identical elements.

The present invention will be described by way of example, and not limitation, Modifications, improvements and additions to the invention described herein may be determined after reading this specification and viewing the accompanying drawings; such modifications, improvements, and additions being considered included in the spirit and broad scope of the present invention and its various embodiments described or envisioned herein.

The present invention provides for magnetic and electromagnetic inspection of materials using a novel sensing arrangement and related methods thereof. The present invention provides for non-contact measurement and analysis to assess damage, structural integrity and materials loss assessment of ferromagnetic objects, particularly those that are elongate, such as, but not limited to, hoist and elevator cables, wire ropes, bridge suspension cables, high-tension conveyor belt re-enforcing cables, reinforcing steel, railroad rail, pipes and ship hulls, and the like.

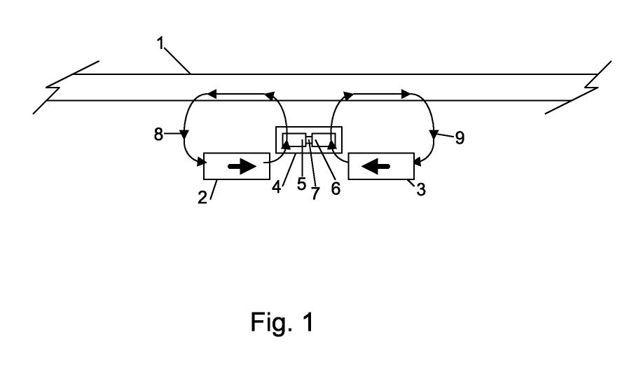

Now referring to one embodiment of the present invention in detail, in FIG. 1 there is shown a side view of the opposing field sensing element according to the present invention in the presence of an intact magnetically permeable member such as a cable. FIG. 1 depicts a ferromagnetic elongate member 1, which may be a cable or the like, situated at a suitable standoff distance above a magnetic sensing element 4. The sensing element 4 may. in one embodiment of the present invention, be comprised of a single axis static magnetic flux sensor such as a commercially available Hall-effect sensor with the addition of flux concentrators that may, for example, be a ferromagnetic structure that is used for flux concentration, or in some embodiments of the present invention it can be a Hall-effect based sensing element having integrated flux concentrators. An integrated flux concentrator may be, in one embodiment of the present invention, a conventional CMOS technology die with an additional ferromagnetic layer, or other semiconductor crystal materials that are suitable for sensors such as hall effect sensors and that have a ferromagnetic layer deposited thereupon. An example of such a hall effect sensor with integrated flux concentrators is the current sensor model number CSA-1V manufactured by Sentron A G of Zug. Switzerland. The CSA-1V contains a conventional CMOS technology Hall Effect sensor with an additional ferromagnetic layer that acts as a magnetic flux concentrator. The ferromagnetic layer acts as a magnetic flux concentrator that provides a high magnetic gain, thus providing a sensor with very high magnetic sensitivity, low offset, and low noise. The CSA-1V is sensitive to a magnetic field that is parallel to the surface of the chip. Thus, in the case of a ferromagnetic elongate member 1 that is continuous (no breaks, damage or defects), there is no magnetic field component that is parallel to the surface of the chip or similar magnetic sensing element 4, and the output of the magnetic sensing element 4 will essentially be null. Such a magnetic flux sensor is sensitive to a magnetic field in an x-axis orientation and not sensitive to a magnetic field in a y-axis orientation. The designation of x-axis and y-axis being arbitrary. The magnetic sensing element 4 has two magnetic excitation flux sources 2 and 3 in close proximity and disposed on the axis of the magnetic sensing element 4. Said magnetic excitation flux cores/sources may be comprised of permanent magnets, DC field coil stators, AC field coils, or the like. In FIG. 1, the Hall Effect sensor 7 is depicted along with flux concentrators 5 and 6. The flux concentrators 5 and 6 are ferromagnetic elements that may be discrete or may be integrated with the Hall Effect sensor 7.

This sensor arrangement allows for the reduction of magnetic excitation core mass due to the requirement that it be in axial alignment with the magnetic sensing element 4, and requires only that sufficient excitation flux is provided to the flux concentrators within the magnetic sensing element 4, which is physically smaller than the outside width dimension of the housing of magnetic sensing element 4 and to be spaced apart laterally, in the case of multi-sensor arrays, at a distance determined by the physical minimum spacing between opposing field sensing elements. This reduces cost and weight of the resulting sensor arrangement.

Flux sources 2 and 3 are arranged such that their like magnetic polarities face each other and thereby intersect the flux concentrators in the magnetic sensing element 4, with substantially a vertical vector component of the magnetic field lines due to the fact that the like magnetic flux fields from flux sources 2 and 3 are “opposing” and cannot cross each other, and hence are “crowded” or forced into substantially the magnetic flux paths depicted.

The flux paths include the standoff paths 8 and 9, both up to the ferromagnetic elongate member 1, and back down. The ferromagnetic elongate member 1 will have a much greater permeability than the sum of the standoff paths and hence can be treated as a magnetic short circuit when intact or with no material loss.

As can be seen in FIG. 1, very little, if any, magnetic flux will cross the sensitive axis of the magnetic sensing element 4 in this depicted configuration. Of note, the “opposing” crowded fields from the excitation flux sources are pushed up vertically, thereby allowing for greater standoff distances and increased sensitivity. Further, as can be seen, the first flux field standoff path 8 serves to magnetize the ferromagnetic elongate member 1 in one direction, with said second flux field standoff path 9 serving to magnetize the ferromagnetic elongate member 1 in the opposite direction. Given substantially equal excitation magnetic flux fields, this serves to degauss the ferromagnetic elongate member 1.

Also, it can be seen that any vertical flutter or displacement of ferromagnetic elongate member 1 above magnetic sensing element 4 will not effect any flux imbalance that will be seen by the sensor flux concentrators, in that the magnetic flux standoff path lengths 8 and 9 will change symmetrically. This becomes of particular importance in applications such as detection of defects or failure modes in a conveyer belt or the like where the ferromagnetic elongate members in the conveyer belt, for example, are subject to regular and frequent vertical displacement that is not indicative of a defect or failure mode in the conveyer belt.

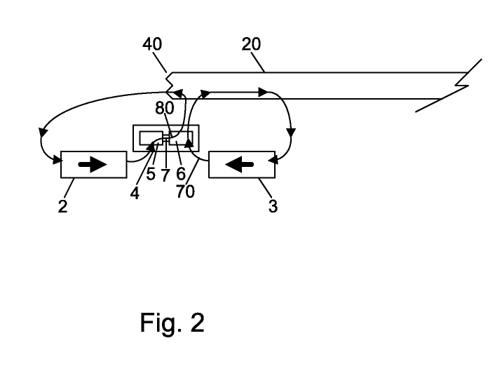

FIG. 2 is a side view of the opposing field sensing element according to the present invention in the presence of a broken or damaged magnetically permeable member such as a cable. It can be seen that the broken or damaged end 40 of a magnetically permeable member 20 effects magnetic flux distortion in field 80. Field 70, however, remains as it would had there not been a break or damage since the flux lines traverse an intact section of the magnetically permeable member. This magnetic flux imbalance will then provide a horizontal component to the flux lines that was not previously present in a continuous, non-damaged magnetically permeable member. This horizontal component, as seen through the flux concentrators and related sensor that may, in one embodiment, be a Hall Effect sensor. will create an output from the magnetic sensing element 4. The output may be, in the case of a Hall Effect sensor, a voltage that is proportional to the horizontal component of flux that is seen by the magnetic sensing element. This output can then be used to indicate a fault or failure condition in a magnetically permeable member. The utility of such an output can be manually interpreted, or in some embodiments, the output may be led into a data processing system for further automated analysis. Depending on the ferromagnetic elongate member being inspected, a plurality of opposing field sensing elements may be employed. For example, a conveyer belt may have a significant width component that requires inspection, and an array of opposing field sensing elements may be configured such that the conveyer belt is continuously scanned. This array may be contained in a housing and further mounted under the conveyer belt itself with suitable mounting hardware and environmental packaging considerations. In addition, such a plurality of opposing field sensing elements may be daisy to chained together using, for example, microcontrollers (UCs) that are connected by way of a Serial Peripheral Interface (SPI) connection that is in turn connected to a data processing system for additional analysis, processing, and output. Other configurations of opposing field sensing elements such as parallel connections, serial connections, star connections, or the like, may also be employed.

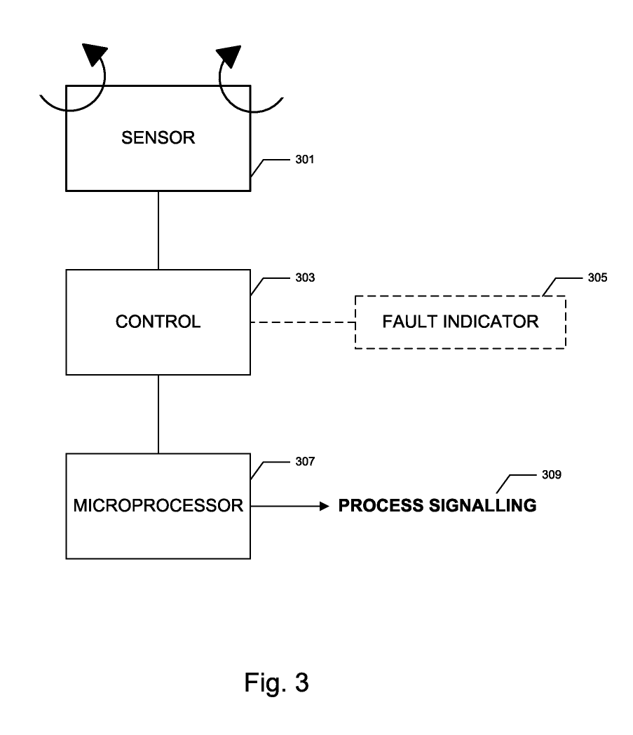

FIG. 3 is a functional block diagram depicting a system of the present invention. As previously described by way of FIGS. 1 and 2 and the accompanying written description, an opposing field sensing element (SENSOR) 301 is provided. The opposing field sensing element (SENSOR) 301 provides an output to a control element 303. This output may, in the case of the Hall Effect sensor embodiment previously described, be a voltage that is proportional to the horizontal (x-axis) component of flux that is seen by the magnetic sensing element (as previously described by way of FIGS. 1 and 2 and the accompanying written description provided herein). This output can then be used to indicate a fault or failure condition in a magnetically permeable member (“member under test”). This output may be received by a control element 303 that contains circuitry that converts the output to an electrical signal that drives a fault indicator 305. Techniques for converting a sensor output to drive a fault indicator 305 are many and are well known. For example, in the case of the output being a voltage that is proportional to the horizontal component of flux that is seen by the magnetic sensing element 301 as previously described, a simple bias circuit such as a resistor based voltage divider network may be electrically connected to the base of a drive transistor. When the output voltage from the opposing field sensing element (SENSOR) 301 reaches a specified level, the drive transistor is provided with a bias voltage from the voltage divider network sufficient to turn the drive transistor to the “on” state. A fault indicator 305 is connected in series with the collector or emitter such that when the drive transistor is biased “on”, current will flow through the fault indicator 305 by way of the collector or emitter branch of the drive transistor, thus powering the fault indicator 305 either directly or with an accompanying relay, switch, transistor, or the like. The fault indicator 305 may be a simple lamp, horn, buzzer or siren that provides audible or visual indication of a fault when energized by way of the drive transistor topology previously described. Other circuits to convert the opposing field sensing element (SENSOR) 301 output to drive a fault indicator 305 can also be readily envisioned by those skilled in the art for which this specification pertains. Of course the control element 303 may also convert the opposing field sensing element (SENSOR) 301 output to a digital output for use by a microprocessor element 307 and subsequent process signaling 309. For example, a voltage output from the opposing field sensing element (SENSOR) 301 may be converted to a binary word by way of any number of commercially available or custom analog to digital converters (A/D converter). Once a microprocessor 307 receives a digital signal that relates to the voltage output from the opposing field sensing element (SENSOR) 301, it can be routed by way of a network, for example, to a remote monitoring site. This process signaling 309 may indicate a fault condition, and may also contain additional appended data such as location, model or serial number, maintenance history, warranty and repair information, previous defects, and the like. The process signaling 309 may also drive various detection and analysis routines that identify failure points, defects, wear, and other such anomalies and discontinuities in ferromagnetic cables. These detection and analysis routines may employ a library or database containing flux signatures that provide indications of failure points, defects, wear, and other such anomalies and discontinuities in ferromagnetic cables. These routines and related database or to library structures may reside on a computer, computers, network devices, storage devices, or the like.

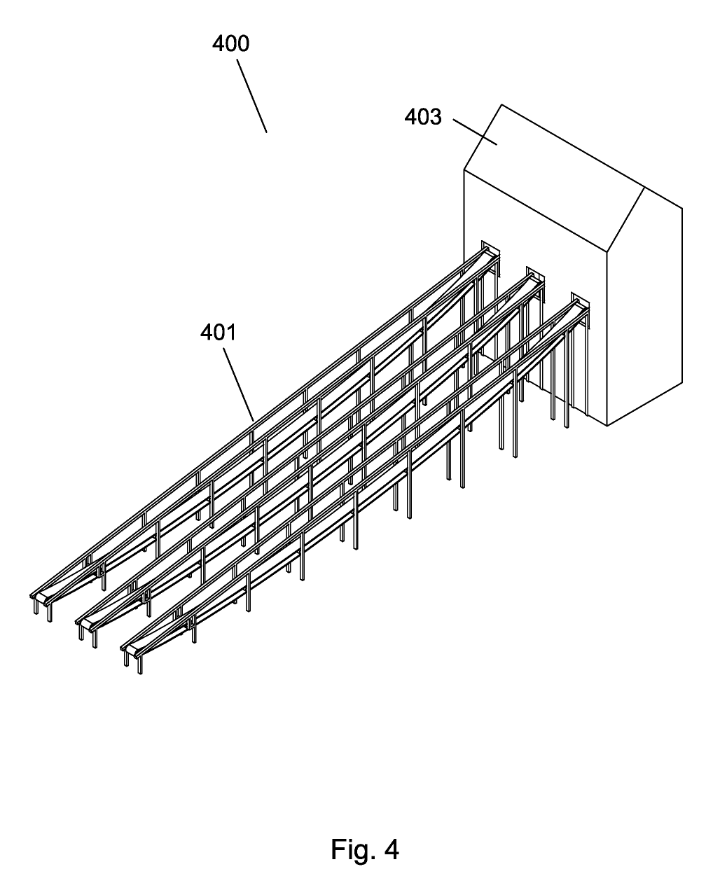

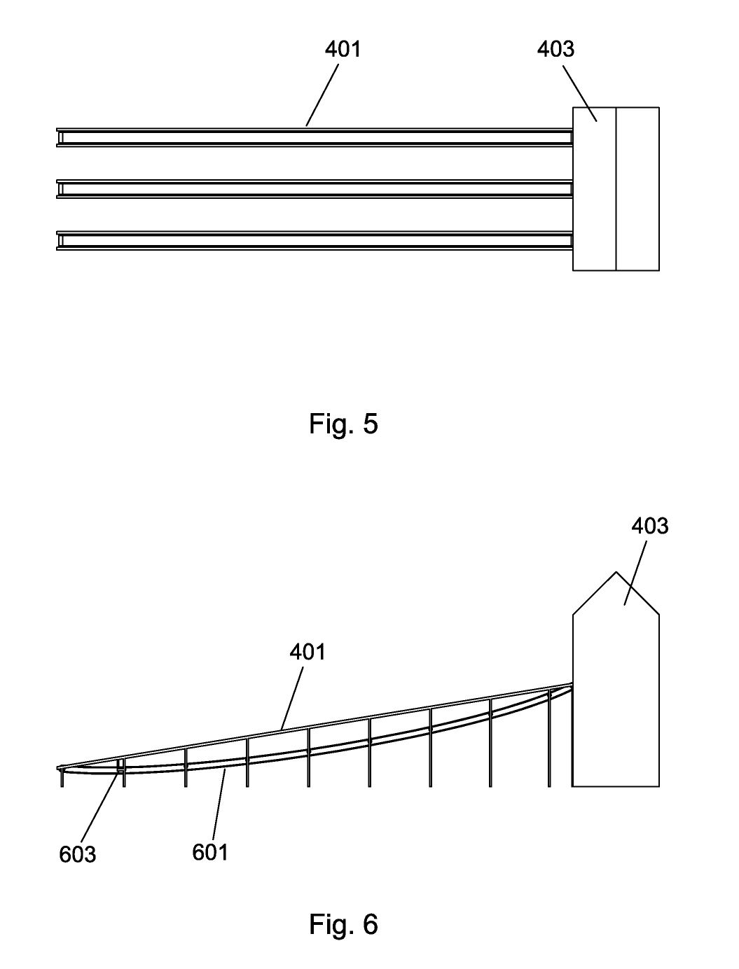

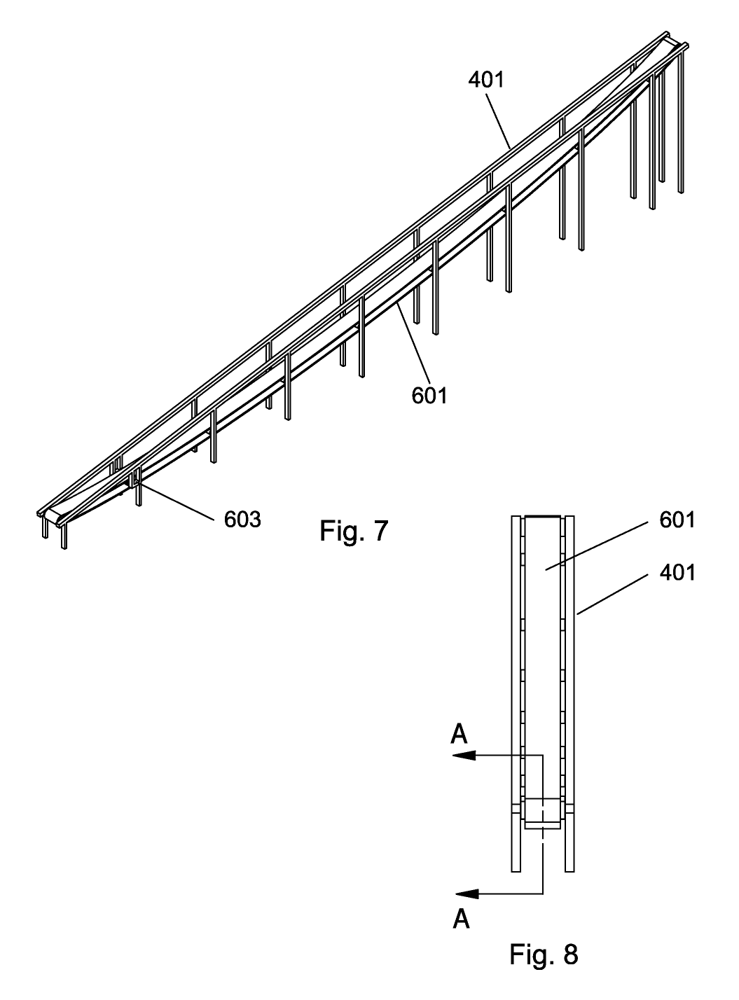

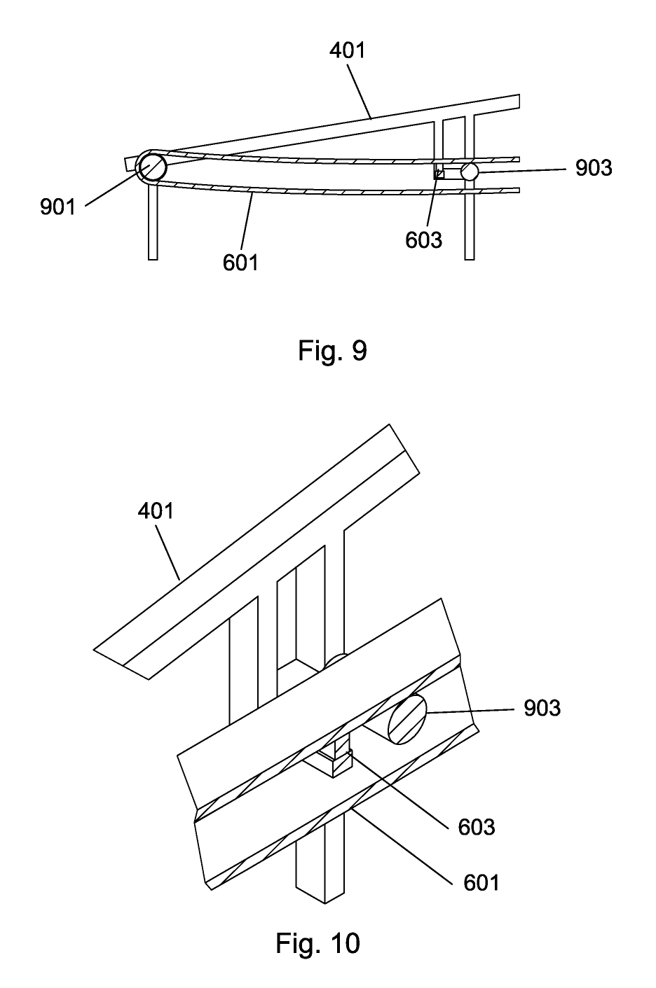

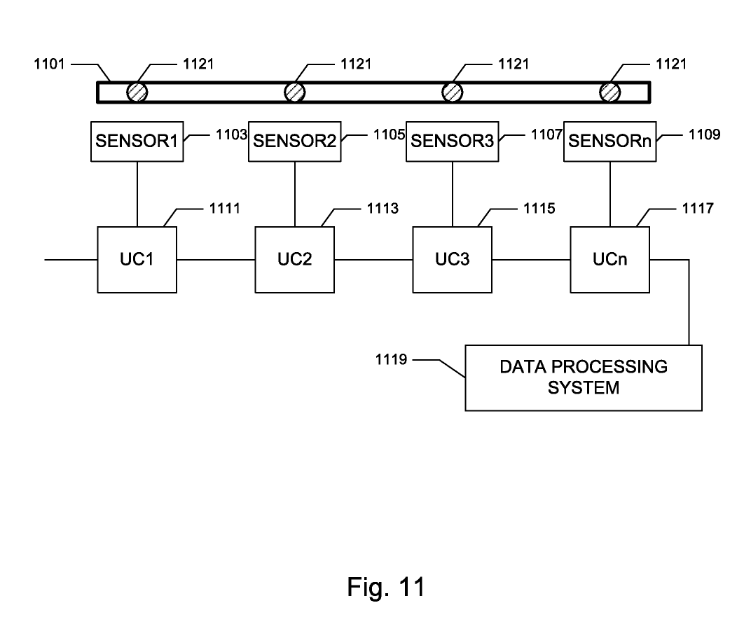

A typical application of the present invention is one of conveyer belt scanning and analysis to predict belt failure or locate belt defects. FIGS. 4-10 depict a typical conveyer belt installation of the present invention. In applying the opposing field sensing element of the present invention to a conveyer belt application, an array of opposing field sensing elements is set up, as will be further described by way of FIG. 11 and the ensuing description thereof. Defects and damage to the ferromagnetic cables within a conveyer belt are detected by way of such an array. FIG. 4 shows a typical installation of the present invention where a multiple conveyer belt system 400 can be seen with each conveyer belt frame 401 being connected to a material processing building 403. FIG. 5 shows a plan view of a typical installation of the present invention and FIG. 6 shows a side view of a typical installation of the present invention where the conveyer belt 601 can be seen with an opposing field sensing element array 603 installed below the top portion of the conveyer belt 601. FIG. 7 shows a perspective view of a typical installation of the present invention. FIG. 8 shows a section of conveyer belt in use with the present invention with a cut line A-A that will be further described by way of FIG. 10. FIG. 9 shows a side view of a single conveyer belt in use with the present invention. In FIG. 9, the rollers 901 and 903 can be seen along with the conveyer belt 601, the frame 401 and the opposing field sensing element array 603. FIG. 10 shows a cutaway view along line A-A of FIG. 8. In FIG. 10, the placement of the opposing field sensing element array 603 can be seen. Spacing between the opposing field sensing element array 603 and the conveyer belt 601, as well as the spacing between each opposing field sensing element and the spacing between the flux source and the to magnetic flux sensor will vary based on the particular application. The opposing field sensing element array 603 may be housed in a suitable environment excluding package such as an extruded aluminum casing, a plastic casing, or the like. The opposing field sensing element array 603 comprises a plurality of opposing field sensing elements as depicted in FIGS. 1 and 2. The plurality of opposing field sensing elements may be connected together through various serial or parallel techniques. FIG. 11 is a functional block diagram of an exemplary n-channel opposing field sensing element array. A conveyor belt in cross section 1101 is depicted at the top of the block diagram. Shown also are ferromagnetic cables 1121 also in cross section. A series of opposing field sensing elements 1103, 1105, 1107 and 1109 can be seen. From each sensor is connected a microcontroller (UC) 1111, 1113, 1115, and 1117. Each microcontroller is daisy chained on to the other using a serial peripheral interface (SPI) or similar such interface. The final microcontroller in this arrangement is in turn connected to a data processing system 1119 by way of a serial peripheral interface (SPI) or similar such interface. The data processing system 1119 contains various detection and analysis routines that identify failure points, defects, wear, and other such anomalies and discontinuities in ferromagnetic cables. These detection and analysis routines may employ a library or database containing flux signatures that provide indications of failure points, defects, wear, and other such anomalies and discontinuities in ferromagnetic cables. In some embodiments of the present invention, a single opposing field sensing element is employed, or a plurality of opposing field sensing elements may be employed either with or without supporting electronics such as the data processing system and associated peripheral interface controllers. The opposing field sensing elements may provide output as simple as a variable voltage or a binary output that may be manually interpreted, or the output of the opposing field sensing elements may be processed from an analog output to a digital data stream and then further processed by way of a data processing system to extract additional information from the opposing field sensing elements that may in turn be used for maintenance, safety, operational planning, or the like.

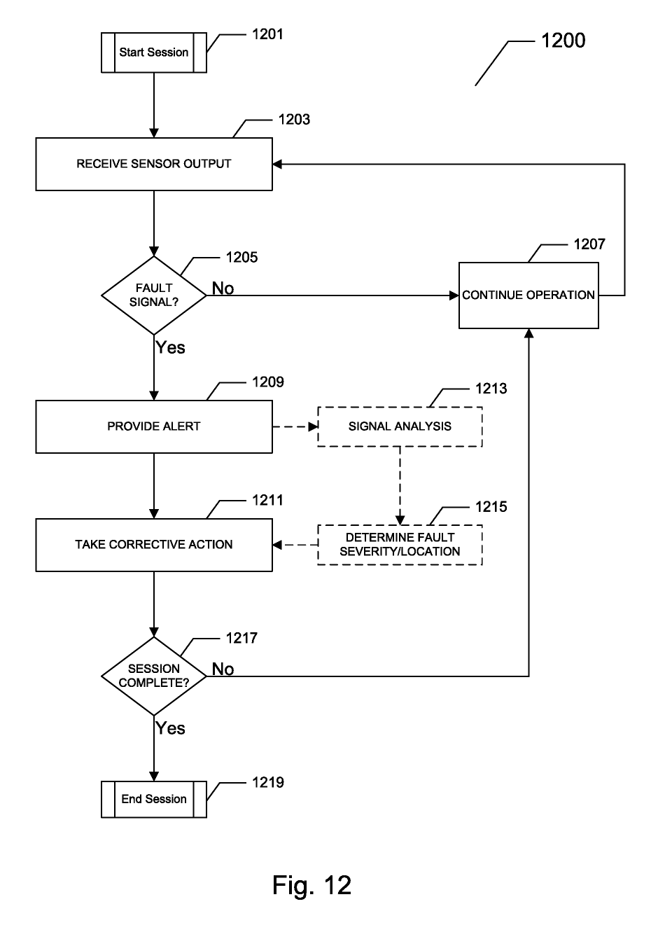

An exemplary method of the present invention is depicted by way of the flowchart of FIG. 12. As previously described herein, the opposing field sensing element output may be converted to a digital output for use by a microprocessor element. For example, a voltage output from the opposing field sensing element may be converted to a binary word by way of any number of commercially available or custom analog to digital converters (A/D converter). Once a microprocessor receives a digital signal that relates to the voltage output from the opposing field sensing element, it can be routed by way of a network, for example, to a remote monitoring site. At the start of a session that may be hosted on any of a number of computing platforms 1201, the sensor output is received in step 1203. The sensor output in step 1203 has been converted from an analog state to a digital state using a commercially available or a custom analog to digital converter. Should the sensor output in step 1203 provide a fault signal in step 1205, an alert is provided in step 1209. Should the sensor output in step 1203 indicate that no fault is present, the process of receiving and analyzing sensor output continues in step 1207. The fault signal in step 1205 is a digital value that corresponds to a fault condition. There may be a plurality of fault conditions that may provide a fault signal by way of a plurality of digital values (for example, binary words mapped to fault conditions). These digital values may indicate a fault condition, and may also contain additional appended data such as location, model or serial number, maintenance history, warranty and repair information, previous defects, and the like. Should a fault signal be sent in step 1205, an alert is provided in step 1209 that may activate a simple visual or audible alert mechanism, or may send a message to a host computer or device by way of a network. Such a network may include, for example, a cellular or radiofrequency network and such a device may include, for example, a smart phone or similar handheld device. A message sent by way of a network, computer to computer communication, radiofrequency communication, data communication, or the like, is considered a report. A report may also be an electronic or a paper document, spreadsheet, or the like. Optionally, once an alert is provided in step 1209, signal analysis may take place in step 1213 that may look at the digital value indicative of the fault condition and determine fault severity, location, or the like in step 1215. Such determination may be made through, for example, a lookup of the digital value in a table or database where various unique digital values are correlated with fault information such as severity, location, or the like. Once an alert of a fault condition is provided in step 1209, corrective action is taken in step 1211. Corrective action may be determined by the signal analysis and determination that optionally occur in steps 1213 and 1215, or corrective action may be determined by information contained in the digital value of the fault signal itself. Corrective actions include, but are not limited to, halting use of the element (such as a conveyer belt), slowing down the operating speed of the element, replacing the element, or the like. Once the corrective action is taken in step 1211, a determination is made as to whether the session is complete. If the session is complete in step 1217, the session is ended in step 1219. If the session is not complete in step 1217, operation is continued in step 1207. Criteria for whether the session is complete include, for example, element operational status. If the element is taken off line for maintenance, end of shift, or the like, the session may be considered complete.

A computer system may comprise a table or a database that correlates digital values from the opposing field sensing element to fault conditions. Additionally, in some embodiments of the present invention, further information is appended to the fault conditions such as, for example, model or serial number, maintenance history, previous faults, operational data such as load, speed, material handled, and the like.

It is, therefore, apparent that there has been provided, in accordance with the various objects of the present invention, a method and apparatus for ferromagnetic cable inspection. While the various objects of this invention have been described in conjunction with preferred embodiments thereof, it is evident that many alternatives, modifications, and variations will be apparent to those skilled in the art. Accordingly, it is intended to embrace all such alternatives, modifications and variations that fall within the spirit and broad scope of the present invention as defined by this specification, claims and the attached drawings.

What is claimed is:

1. An opposing field sensing element for ferromagnetic cable inspection comprising:
a first magnetic flux source and a second magnetic flux source wherein like polarities of the first magnetic flux source and the second magnetic flux source face each other;
a magnetic flux sensor sensitive to a magnetic field in an x-axis orientation and not sensitive to a magnetic field in a y-axis orientation, the magnetic flux sensor being situated between the first magnetic flux source and the second magnetic flux source; and
a magnetic flux concentrator located proximate said magnetic flux sensor.

2. The opposing field sensing element of claim 1, further comprising a second magnetic flux concentrator located proximate said magnetic flux sensor wherein the first magnetic flux concentrator is located in the flux path of the first magnetic flux source and the second magnetic flux concentrator is located in the flux path of the second magnetic flux source.

3. The opposing field sensing element of claim 1, wherein the magnetic flux concentrator is integral with the magnetic flux sensor.

4. The opposing field sensing element of claim 1, wherein the magnetic flux sensor is a hall effect sensor.

5. The opposing field sensing element of claim 4, wherein the magnetic flux concentrator is a ferromagnetic layer on a semiconductor crystal.

6. The opposing field sensing element of claim 1, further comprising an analog to digital converter to provide a digital output indicative of ferromagnetic cable condition.

7. A system for ferromagnetic cable inspection comprising:
a path for movement of a ferromagnetic cable;
an opposing field sensing element for ferromagnetic cable inspection comprising a first magnetic flux source and a second magnetic flux source wherein like polarities of the first magnetic flux source and the second magnetic flux source face each other and wherein the flux from the first magnetic flux source and the flux from the second magnetic flux source penetrate the ferromagnetic cable orthogonally with respect to the ferromagnetic cable;
a magnetic flux sensor sensitive to a magnetic field in an x-axis orientation and not sensitive to a magnetic field in a y-axis orientation, the magnetic flux sensor being situated between the first magnetic flux source and the second magnetic flux source; and
a magnetic flux concentrator located proximate said magnetic flux sensor.

8. The system for ferromagnetic cable inspection of claim 7, further comprising a second magnetic flux concentrator located proximate said magnetic flux sensor wherein the first magnetic flux concentrator is located in the flux path of the first magnetic flux source and the second magnetic flux concentrator is located in the flux path of the second magnetic flux source.

9. The system for ferromagnetic cable inspection of claim 7, wherein the magnetic flux concentrator is integral with the magnetic flux sensor.

10. The system for ferromagnetic cable inspection of claim 7, wherein the magnetic flux sensor is a hall effect sensor.

11. The system for ferromagnetic cable inspection of claim 10, wherein the magnetic flux concentrator is a ferromagnetic layer on a semiconductor crystal.

12. The system for ferromagnetic cable inspection of claim 7, further comprising an analog to digital converter to provide a digital output indicative of ferromagnetic cable condition.

13. The system for ferromagnetic cable inspection of claim 12, further comprising a processor configured to receive a digital output indicative of ferromagnetic cable condition.

14. The system for ferromagnetic cable inspection of claim 13, further comprising a database of fault conditions correlated with digital output values.

15. The system for ferromagnetic cable inspection of claim 7, further comprising a plurality of opposing field sensing elements.

16. The system for ferromagnetic cable inspection of claim 15, further comprising a controller for operatively coupling the plurality of opposing held sensing elements to a data processing system.

17. A method for ferromagnetic cable inspection comprising the steps of
receiving on a computer output from the opposing field sensing element of claim 1;
analyzing on a computer the output from the opposing field sensing element to determine if a fault condition in a ferromagnetic cable under inspection has occurred; and
providing an alert if a fault condition has occurred.

18. The method for ferromagnetic cable inspection of claim 17, wherein the alert is a visual indicator.

19. The method for ferromagnetic cable inspection of claim 17, wherein the alert is an audible indicator.

20. The method for ferromagnetic cable inspection of claim 17, wherein the alert is a report.
